(19) United States
(12) Patent Application Publication
(10) Pub. No.: US 2026/0164660 A1
(43) Pub. Date: Jun. 11, 2026

(54) SEMICONDUCTOR DEVICE AND MANUFACTURING METHOD OF SEMICONDUCTOR DEVICE

(71) Applicant: SK hynix Inc., Gyeonggi-do (KR)

(72) Inventors: Seok Hyun LEE, Gyeonggi-do (KR); Hyo Sub YEOM, Gyeonggi-do (KR)

(21) Appl. No.: 19/178,870

(22) Filed: Apr. 15, 2025

(30) Foreign Application Priority Data
Nov. 28, 2024 (KR) 10-2024-0174037

(51) Int. Cl. H10B 43/27; H10B 41/10; H10B 41/27; H10B 41/41; H10B 43/10; H10B 43/40

(52) U.S. Cl. CPC H10B 43/27; H10B 41/10; H10B 41/27; H10B 41/41; H10B 43/10; H10B 43/40

(57) ABSTRACT

A semiconductor device may include a stack including a staircase structure; an interlayer insulating layer disposed at a level corresponding to the stack and in contact with the staircase structure in a first direction, a boundary between the interlayer insulating layer and the staircase structure extending in a second direction intersecting the first direction; and at least one support disposed at the boundary and including an insulating plug extending through the interlayer insulating layer and the stack and a stop layer extending in the first direction through the insulating plug.

### CROSS-REFERENCE TO RELATED APPLICATION

This application claims priority under 35 U.S.C. § 119 to Korean Patent Application No. 10-2024-0174037 filed on Nov. 28, 2024, which is incorporated herein by reference in its entirety.

### BACKGROUND

### 1. Technical Field

Embodiments of the present disclosure relate generally to an electronic device, and more particularly, to a semiconductor device and a manufacturing method of the semiconductor device.

### 2. Related Art

The degree of integration of a semiconductor device is mainly determined by the area occupied by a unit memory cell. Recently, as the improvement in the degree of integration of a semiconductor device for forming memory cells in a single layer on a substrate reaches a limit, three-dimensional semiconductor devices which stack memory cells in multiple layers over a substrate have been proposed. However, further improvements are needed in the operational reliability and performance characteristics of the three-dimensional semiconductor devices and various structures and manufacturing methods are being developed.

### SUMMARY

In an embodiment of the present disclosure, a semiconductor device may include a stack including a staircase structure; an interlayer insulating layer disposed at a level corresponding to the stack, the interlayer insulating layer being in contact with the staircase structure in a first direction, wherein boundary between the interlayer insulating layer and the staircase structure is extending in a second direction intersecting the first direction; and at least one support disposed at the boundary and including an insulating plug extending through the interlayer insulating layer and the stack and a stop layer extending in the first direction through the insulating plug.

In an embodiment of the present disclosure, a semiconductor device may include a stack including first material layers and second material layers that are alternately stacked; an interlayer insulating layer disposed at a level corresponding to the stack, the interlayer insulating layer being in contact with the stack in a first direction, wherein a boundary between the interlayer insulating layer and the stack is extending in a second direction intersecting the first direction; an insulating plug disposed at the boundary; a conductive pattern having a slit shape traversing the insulating plug and having a wider width than the insulating plug in the first direction; and a liner surrounding the conductive pattern.

In an embodiment of the present disclosure, a manufacturing method of a semiconductor device may include forming a stack including a staircase structure; forming an interlayer insulating layer disposed at a level corresponding to the stack and in contact with the staircase structure in a first direction; forming an insulating plug at a boundary between the interlayer insulating layer and the staircase structure; forming a first slit passing through the insulating plug and extending in the first direction; and forming a stop layer in the first slit.

### BRIEF DESCRIPTION OF THE DRAWINGS

FIGS. 1A to 1C are diagrams illustrating the structure of a semiconductor device in accordance with an embodiment of the present disclosure.

FIGS. 2A to 2D are diagrams illustrating the structure of a semiconductor device in accordance with an embodiment of the present disclosure.

FIGS. 3A, 4A, and 5A and FIGS. 3B, 4B, and 5B are diagrams for describing a manufacturing method of a semiconductor device in accordance with an embodiment of the present disclosure.

FIGS. 6A, 7A, 8A, 9A, 10A, 11A, 12A, and 13A and FIGS. 6B, 7B, 8B, 9B, 10B, 11B, 12B, and 13B are diagrams for describing a manufacturing method of a semiconductor device in accordance with an embodiment of the present disclosure.

FIG. 14 is a diagram illustrating the structure of a semiconductor device in accordance with an embodiment of the present disclosure.

FIG. 15 is a configuration diagram of a semiconductor device in accordance with an embodiment of the present disclosure.

FIG. 16 is a configuration diagram of a semiconductor device in accordance with an embodiment of the present disclosure.

### DETAILED DESCRIPTION

Various embodiments of the present disclosure are directed to a three-dimensional semiconductor device (hereinafter referred to simply as semiconductor device) having an improved stable structure and improved characteristics. Various embodiments of the present disclosure are also directed to a manufacturing method of the semiconductor device.

By stacking memory cells in three dimensions, it is possible to improve the degree of integration of a semiconductor device. It is also possible to provide a semiconductor device having a stable structure and improved reliability.

Hereafter, embodiments in accordance with the technical concepts of the present disclosure will be described with reference to the accompanying drawings.

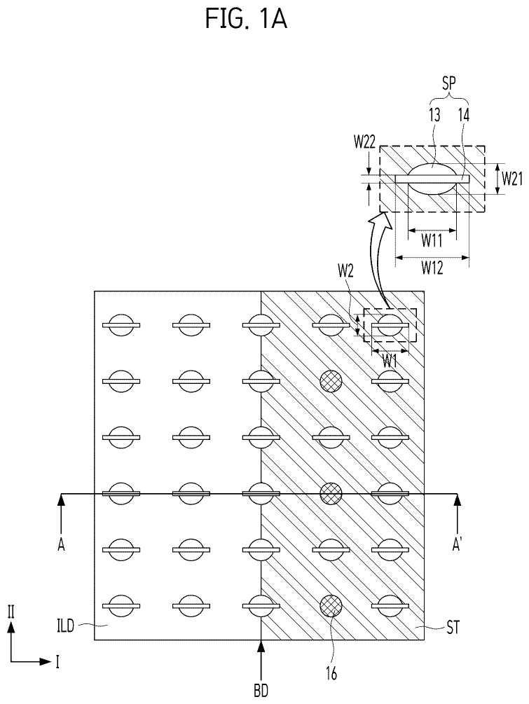

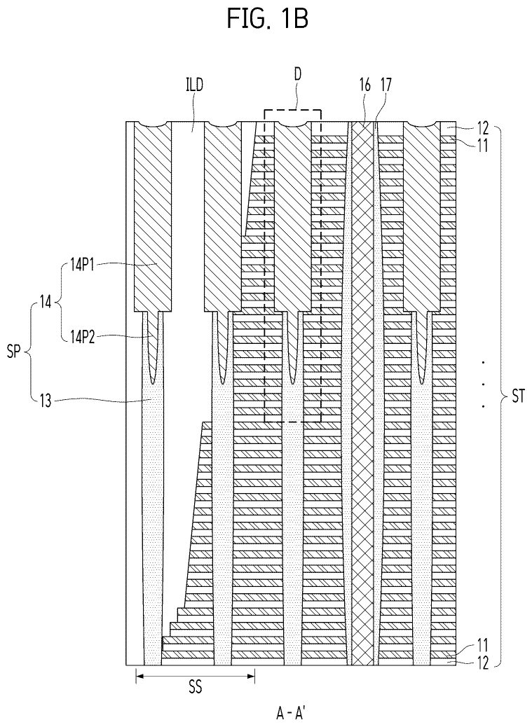

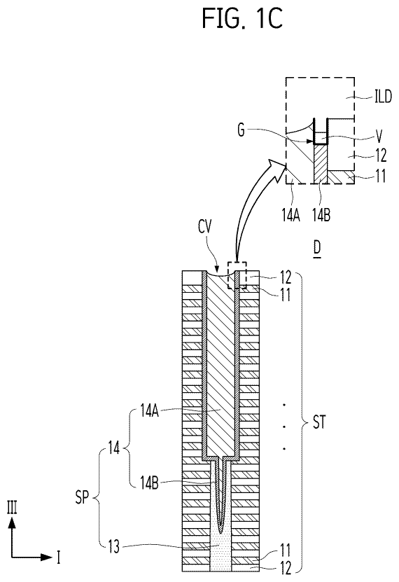

FIGS. 1A to 1C are diagrams illustrating a structure of a semiconductor device in accordance with an embodiment of the present disclosure. FIG. 1B is a cross-sectional view taken along line A-A′ of FIG. 1A, and FIG. 1C is an enlarged view of region D of FIG. 1B.

Referring to FIGS. 1A to 1C, the semiconductor device may include a stack ST, an interlayer insulating layer ILD, and at least one support SP. The semiconductor device may further include a contact plug 16 and an insulating spacer 17.

The stack ST may include first material layers 11 and second material layers 12 that are alternately stacked. For example, the first material layers 11 may each include an insulating material such as a nitride or a conductive material such as polysilicon or a metal. The second insulating layers 12 may each include an insulating material such as an oxide. The stack ST may include a staircase structure SS.

The interlayer insulating layer ILD may be disposed at a level corresponding to the level of the stack ST. An entire sidewall of the stack ST may have a staircase structure SS. The staircase structure SS and the interlayer insulating layer ILD may contact each other in a first direction I. A surface where the staircase structure SS and the interlayer insulating layer ILD contact each other may be defined as a boundary BD. In a plane defined by the first direction I and a second direction II intersecting the first direction I, the boundary BD may extend in the second direction II. When the stack ST includes a plurality of staircases, a plurality of boundaries BD may be defined to correspond to sidewalls of the staircases or the boundary BD may be defined at a predetermined width.

The support SP may be disposed at the boundary BD between the staircase structure SS and the interlayer insulating layer ILD. The support SP may extend through the stack ST and/or the interlayer insulating layer ILD. For example, the support SP may extend in a third direction III intersecting the first direction I and the second direction II. The third direction III may be perpendicular to the plane defined by the first direction I and the second direction II. The semiconductor device may include a plurality of supports SP arranged in the first direction I and the second direction II. The supports SP may be arranged along the boundary BD extending in the second direction II. The support SP may have different widths in the first direction I and the second direction II. A first width W1 in the first direction I may be greater than a second width W2 in the second direction II.

The support SP may include an insulating plug 13 and a stop layer 14. The insulating plug 13 may have a pillar shape extending in the third direction III through the stack ST and/or the interlayer insulating layer ILD. In a plan view, the stop layer 14 may extend in the first direction I through the insulating plug 13. In a cross section, the stop layer 14 may have a shorter height than the insulating plug 13. For example, an upper surface of the stop layer 14 and an upper surface of the insulating plug 13 may be disposed at the same or substantially the same level, and a lower surface of the insulating plug 13 may be disposed at a lower level than a lower surface of the stop layer 14.

The stop layer 14 may include a first portion 14P1 having a slit shape traversing the insulating plug 13 as shown in FIG. 1A. The stop layer 14 may also have a second portion 14P2 protruding from a lower surface of the first portion 14P1 as shown in FIG. 1B. The second portion 14P2 may have a thinner width than the first portion 14P1. An upper surface of the first portion 14P1 may include a curved surface CV that is inwardly recessed. In an embodiment, the stop layer 14 may include only the first portion 14P1 and may not include the second portion 14P2. It is also possible for only some of the plurality of supports SP to include the second portions 14P2 or for the second portions 14P2 included in the plurality of supports SP to have different heights.

The insulating plug 13 may have a first width W11 in the first direction I and a second width W21 in the second direction II. The first width W11 and the second width W21 may be the same or substantially the same as or different from each other. For example, the first width W11 may be greater than the second width W21. The stop layer 14 may have a first width W12 in the first direction I and a second width W22 in the second direction II. For example, the first width W12 may be wider than the second width W22. In the first direction I, the first width W12 of the first portion 14P1 may be wider than the first width W11. In the second direction II, the second width W22 of the first portion 14P1 may be thinner than the second width W21. For example, in an embodiment, the support SP may include only the insulating plug 13. In such a case, the first width W11 of the insulating plug 13 may be wider than the second width W21 of the insulating plug 13.

The stop layer 14 may be composed of a single layer or a multilayer layer. For example, the stop layer 14 may include a conductive pattern 14A and a liner 14B surrounding the conductive pattern 14A. The liner 14B may be disposed between the conductive pattern 14A and the insulating plug 13, and may surround a lower surface and sidewalls of the conductive pattern 14A. The liner 14B may include an insulating material such as nitride.

The liner 14B may contact the conductive pattern 14A. At the contact interface between the liner 14B and the conductive pattern 14A, an upper (or top) surface of the liner 14B may be disposed at the same level as an upper (or top) surface of the conductive pattern 14A or disposed at a lower level than the upper surface of the conductive pattern 14A. When the upper surface of the liner 14B is disposed at the lower level than the upper surface of the conductive pattern 14A, a groove G is formed around the conductive pattern 14A. When the groove G is filled with the interlayer insulating layer ILD a void V may exist in the groove G, e.g., at the lower end of the groove G.

The insulating plug 13 and the stop layer 14 may include different materials. The stop layer 14 may include a material having higher, or superior rigidity than the insulating plug 13. For example, the stop layer 14 may include a material having a higher density than the insulating plug 13 or a material having a greater elastic modulus than the insulating plug 13. For example, the insulating plug 13 may include oxide, and the stop layer 14 may include at least one of polysilicon and nitride. In an embodiment, the conductive pattern 14A may include polysilicon, and the liner 14B may include nitride.

The contact plug 16 may extend through the interlayer insulating layer ILD and/or the stack ST. The contact plug 16 may be disposed between the supports SP. The insulating spacer 17 may surround the sidewalls of the contact plug 16. The contact plug 16 may electrically connect a wiring line located below the stack ST and a wiring line located above the stack ST to each other. For example, a peripheral circuit may be disposed below the stack ST, and the contact plug 16 may be electrically connected to the peripheral circuit.

According to the structure described above, the boundary BD may exist between the interlayer insulating layer ILD and the stack ST. The boundary BD may extend along the second direction II. Because the boundary BD is vulnerable to stress, when a defect such as an oxidation defect or a crack occurs, the defect may be transferred along the boundary BD. Accordingly, by locating the support SP at the boundary BD, it is possible to stop the defect from being transferred along the boundary BD. The support SP includes a material having excellent rigidity, and thus, may effectively stop the transfer of the defect. In addition, because the support SP has a shape in which it has a wider width in the first direction I than in the second direction II, even though a transfer direction of the defect is changed, the support SP may stop the transfer of the defect.

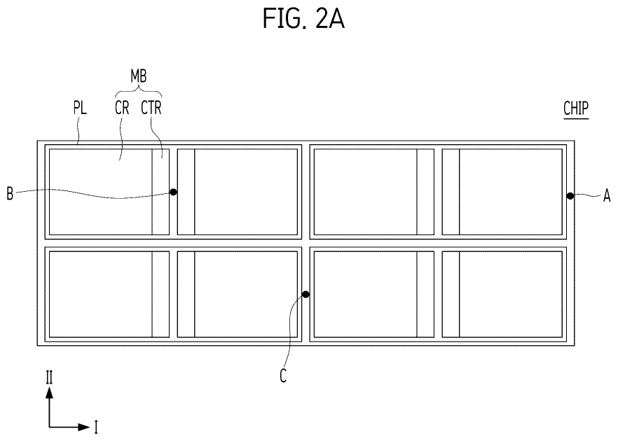

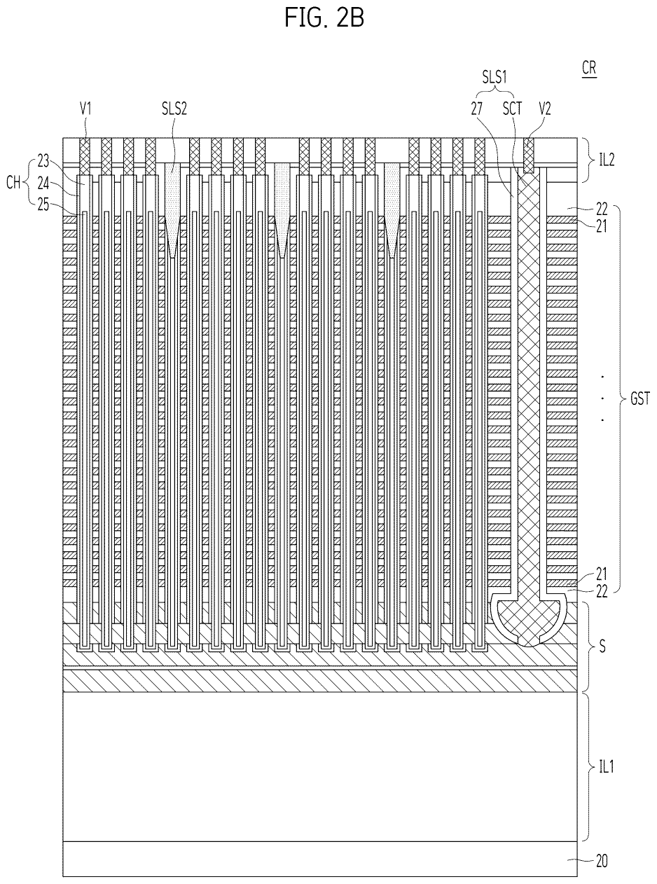

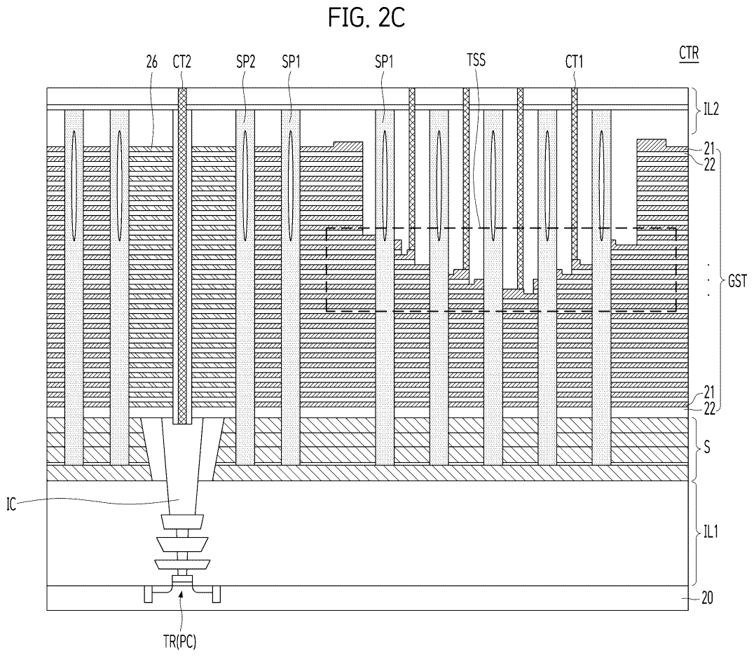

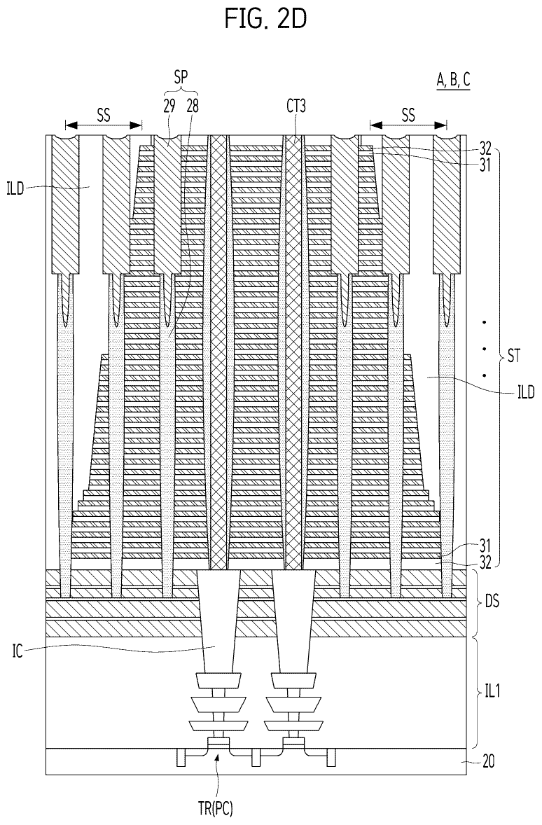

FIGS. 2A to 2D are diagrams illustrating the structure of a semiconductor device in accordance with an embodiment of the present disclosure. Hereinafter, any content overlapping with the previously described content may be omitted.

Referring to FIG. 2A, the semiconductor device may be a semiconductor chip CHIP. The semiconductor chip CHIP may include a plurality of planes PL. For example, the semiconductor chip CHIP may include planes PL arranged in the first direction I and the second direction II intersecting the first direction I. Each of the planes PL may include a plurality of memory blocks MB. The memory blocks MB may be arranged in the first direction I and/or the second direction II. For example, a memory block MB may be a unit in which an erase operation is performed.

For example, each of the memory blocks MB may include a cell region CR and a contact region CTR. In the case of the memory blocks MB which are adjacent to each other in the first direction I, the contact regions CTR may be disposed between the cell regions CR, and the contact regions CTR may be disposed at a boundary between the memory blocks MB. The cell region CR may be a region where memory cells are stacked. The contact region CTR may be a region where an interconnection structure for applying a bias for driving the stacked memory cells is located.

Referring to FIG. 2B, a substrate 20, a gate structure GST, a channel structure CH, a source structure S, a first slit structure SLS1, a second slit structure SLS2, a first interlayer insulating layer IL1, a second interlayer insulating layer IL2, a first via V1, and a second via V2 may be disposed in the cell region CR.

The first interlayer insulating layer IL1 may be disposed on the substrate 20, and the source structure S may be disposed on the first interlayer insulating layer IL1. The source structure S may be composed of a single layer or a multilayer layer. The source structure S may include a conductive material such as polysilicon or metal.

The gate structure GST may be disposed on the source structure S. The gate structure GST may include conductive layers 21 and insulating layers 22 that are alternately stacked. The conductive layers 21 may be gate lines such as a drain select line, a source select line, and word lines. The conductive layers 21 may each include a conductive material such as polysilicon or metal. The insulating layers 22 are used to insulate the stacked conductive layers 21 from each other, and may each include an insulating material such as oxide, nitride, or air gap.

The channel structure CH may extend into the source structure S through the gate structure GST. The channel structure CH may include a channel layer 23, a memory layer 24, and an insulating core 25. The channel layer 23 may be connected to the source structure S. The memory layer 24 may include at least one of a tunneling layer, a data storage layer, and a blocking layer. The data storage layer may include a floating gate, polysilicon, a charge trap material, nitride, a variable resistance material, or the like.

The first slit structure SLS1 may be disposed between the channel structures CH, and may extend into the source structure S through the gate structure GST. The first slit structure SLS1 may include a source contact plug SCT electrically connected to the source structure S and an insulating spacer 27 surrounding sidewalls of the source contact plug SCT. The second slit structure SLS2 may extend through the gate structure GST. For example, the second slit structure SLS2 may have a depth deep enough to pass through the conductive layers 21 corresponding to the drain select lines. The second slit structure SLS2 may include an insulating material such as oxide or nitride.

The second interlayer insulating layer IL2 may be disposed on the gate structure GST. The first via V1 may extend through the second interlayer insulating layer IL2, and may be connected to the channel structure CH. A plurality of the first vias V1 may each extend through the second interlayer insulating layer IL2, and may be connected to a corresponding channel structure CH of the plurality of the channel structures CH. The second via V2 may extend through the second interlayer insulating layer IL2, and may be connected to the source contact plug SCT.

Referring to FIG. 2C, a substrate 20, a peripheral circuit PC, a first interlayer insulating layer IL1, a source structure S, a gate structure GST, a second interlayer insulating layer IL2, a first contact plug CT1, a second contact plug CT2, a first support SP1, and a second support SP2 may be disposed in the contact region CTR.

A transistor TR may be disposed on the substrate 20, and may be part of peripheral circuit PC. The peripheral circuit PC may include a page buffer, a row decoder, and the like. An interconnection structure IC may include a via, a wiring line, and the like, and may be disposed in the first interlayer insulating layer IL1. The interconnection structure IC may be connected to the peripheral circuit PC.

The source structure S may be disposed on the first interlayer insulating layer IL1, and the gate structure GST may be disposed on the source structure S. The second interlayer insulating layer IL2 may be disposed on the gate structure GST.

The gate structure GST may include a trench-type staircase structure TSS, and staircases may be disposed on a bottom surface of a trench. Pad regions of the conductive layers 21 may be defined by the staircase structure TSS. The pad region of the conductive layer 21 may have a thicker thickness than the remaining region of the conductive layer 21. The first contact plugs CT1 may extend through the second interlayer insulating layer IL2, and may be connected to the pad regions, respectively. The first supports SP1 may be disposed between the first contact plugs CT1. The first supports SP1 may extend into the source structure S through the second interlayer insulating layer IL2 and the gate structure GST. The first supports SP1 may each include an insulating material such as oxide or nitride, a conductive material such as polysilicon or metal, or a combination thereof.

The second supports SP2 may each have a line shape, and may extend into the source structure S through the gate structure GST. Between the second supports SP2, the gate structure GST may include sacrificial layers 26 instead of the conductive layers 21. The sacrificial layers 26 may be layers which were not replaced with the conductive layers 21 in a manufacturing process. Between the second supports SP2, the gate structure GST may include the sacrificial layers 26 and the insulating layers 22 that are alternately stacked. The second contact plug CT2 may extend through the sacrificial layers 26 and the insulating layers 22 that are alternately stacked, and may be electrically connected to the interconnection structure IC.

FIG. 2D is a cross-sectional view of region A, region B, or region C. Region A may be an edge of the semiconductor chip CHIP. Region B may be a region between adjacent memory blocks MB, and may be an edge of the memory block MB or an edge of the contact region CTR. Region C may be a region between adjacent planes PL, and may be an edge of the plane PL. Referring to FIG. 2D, a peripheral circuit PC, a first interlayer insulating layer IL1, a dummy source structure DS, a stack ST, and an interlayer insulating layer ILD may be disposed over a substrate 20.

A transistor TR may be disposed on the substrate 20, and may belong to the peripheral circuit PC. An interconnection structure IC may be disposed in the first interlayer insulating layer IL1, and may be connected to the peripheral circuit PC. The dummy source structure DS may be disposed on the first interlayer insulating layer IL1, and may be disposed at a level corresponding to the source structure S. The dummy source structure DS may be composed of a single layer or a multilayer layer. The stack ST may be disposed on the dummy source structure DS.

The stack ST may include first material layers 31 and second material layers 32 that are alternately stacked. The first material layers 31 may each include a material having a high etching selectivity with respect to the second material layers 32. For example, the first material layers 31 may each include nitride, and the second material layers 32 may each include oxide. The first material layers 31 may be disposed at levels corresponding to the conductive layers 21, and may each include the same or substantially the same material as the sacrificial layers 26. The second material layers 32 may be disposed at levels corresponding to the insulating layers 22, and may be layers connected to the insulating layers 22.

The stack ST may include a staircase structure SS on a sidewall thereof. The staircase structure SS may be a structure patterned together with the staircase structure TSS in a process of forming the staircase structure TSS of the contact region CTR. Unlike the staircase structure TSS of the contact region CTR, the staircase structure SS might not be connected to the contact plugs, and may be entirely formed on the sidewall of the stack ST. The staircase structure SS may contact the interlayer insulating layer ILD, and a step between staircases of the staircase structure SS may be greater than that between staircases of the staircase structure TSS defining the pad regions.

A third contact plug CT3 may extend through the stack ST, and may be electrically connected to the interconnection structure IC. The third contact plug CT3 may be electrically connected to the peripheral circuit PC through the interconnection structure IC.

The interlayer insulating layer ILD may be disposed at a level corresponding to the stack ST. The interlayer insulating layer ILD may contact the sidewall of the stack ST, and may contact the staircase structure SS. For example, the stack ST may be disposed between adjacent memory blocks MB, and the gate structures GST located on both sides of the stack ST may belong to different memory blocks MB, respectively.

Supports SP may extend through the stack ST and/or the interlayer insulating layer ILD, and may be disposed at a boundary between the interlayer insulating layer ILD and the stack ST. Each of the supports SP may include an insulating plug 28 and a stop layer 29. The stop layer 29 may include a material having higher, or superior rigidity than the insulating plug 28. For example, the stop layer 29 may have a higher density than the insulating plug 28 or have a greater elastic modulus than the insulating plug 28.

According to the structure described above, stress may be concentrated at the edge of the semiconductor chip CHIP, between adjacent memory blocks MB, or between adjacent planes PL, and a crack may be transferred along the boundary between the stack ST and the interlayer insulating layer ILD. According to an embodiment of the present disclosure, the support SP is disposed at the edge of the semiconductor chip CHIP, between the adjacent memory blocks MB, or between the adjacent planes PL. The support SP may have a different structure from the first and second supports SP1 and SP2 of the contact region CTR, and may include the stop layer 29. By locating the support SP including the stop layer 29 at the boundary between the interlayer insulating layer ILD and the stack ST, it is possible to block the transfer of a defect.

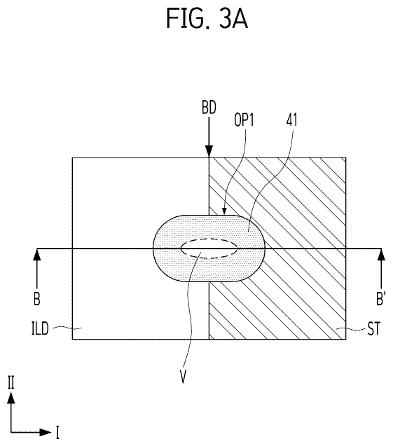

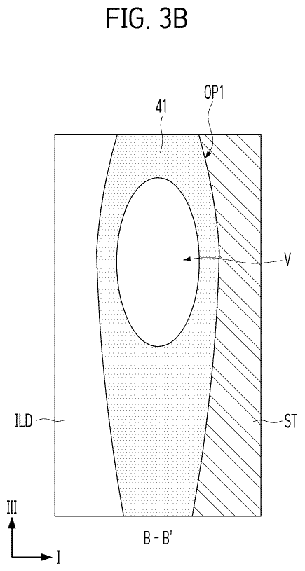

FIGS. 3A, 4A, and 5A and FIGS. 3B, 4B, and 5B are diagrams for describing a manufacturing method of a semiconductor device in accordance with an embodiment of the present disclosure. FIGS. 3B, 4B, and 5B are cross-sectional views taken along lines B-B′ of FIGS. 3A, 4A, and 5A, respectively. Hereinafter, any content overlapping with the previously described content may be omitted.

Referring to FIGS. 3A and 3B, a stack ST and an interlayer insulating layer ILD may be formed. The stack ST and the interlayer insulating layer ILD may be disposed at a corresponding level, and may contact each other in the first direction I. A boundary BD may exist between the stack ST and the interlayer insulating layer ILD, and may extend in the second direction II.

Subsequently, a first opening OP1 may be formed at the boundary BD between the stack ST and the interlayer insulating layer ILD. In a plane defined by the first direction I and the second direction II, a width of the first opening OP1 in the first direction I may be wider than a width of the first opening OP1 in the second direction II. For example, the first opening OP1 may have an oval shape with the pair of opposite sides in the second direction II that are substantially flat, while the pair of opposite sides in the first direction I are curved. In a cross section defined by the first direction I and the third direction III, the first opening OP1 may have a bowing shape. The first opening OP1 may have an oval shape with the pair of opposite sides in the second direction II that are substantially flat, while the pair of opposite sides in the first direction I are curved. The first opening OP1 may have a thinner width in a lower surface thereof than in an upper surface thereof. A bowing region may be disposed between an upper region and a lower region, and may have a wider width than the upper surface and the lower surface.

Subsequently, an insulating plug 41 may be formed in the first opening OP1. For example, the insulating plug 41 may be formed by depositing an insulating material in the first opening OP1. The insulating plug 41 may include a void V, and the void V may be disposed in the bowing region. The void V may be an empty space in which the insulating material is not deposited.

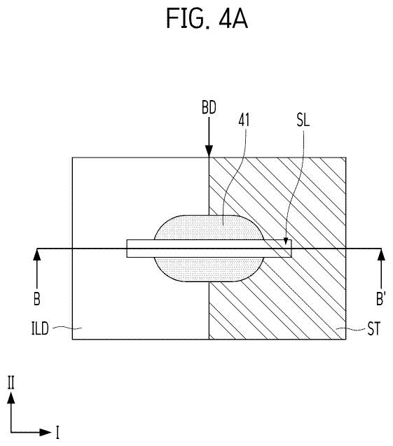

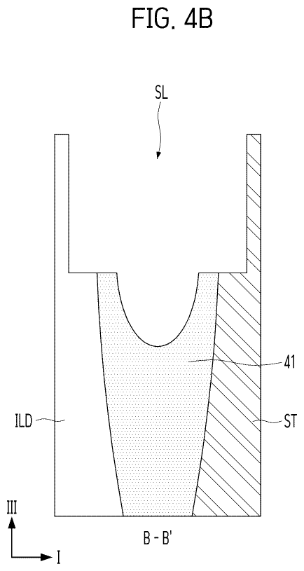

Referring to FIGS. 4A and 4B, a slit SL extending in a direction intersecting the boundary BD may be formed. In a plan view, the slit SL may pass through the insulating plug 41, and may extend in the first direction I. In the first direction I, the slit SL may have a wider width than the insulating plug 41. In the second direction II, the slit SL may have a thinner width than the insulating plug 41.

A height of the slit SL may be shorter than a height of the insulating plug 41. The void V may be opened in a process of forming the slit SL. Accordingly, the slit SL may be connected to the void V, and may form a protrusion portion of the slit SL protruding into the insulating plug 41. For example, in an embodiment, the insulating plug 41 might not include the void V or the void V might not be exposed in the process of forming the slit SL. In such a case, the slit SL might not include the protrusion portion.

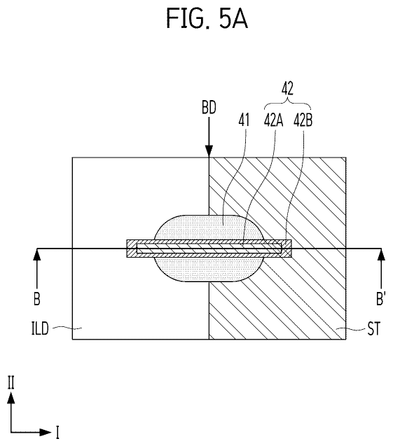

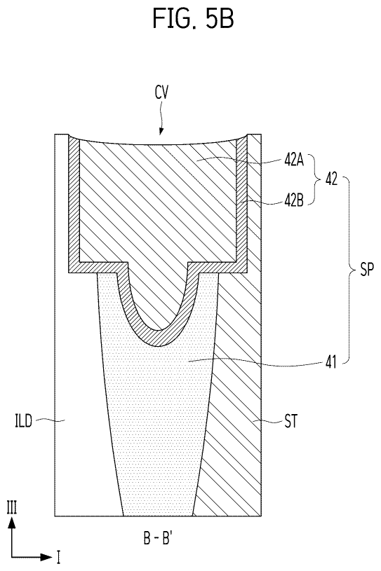

Referring to FIGS. 5A and 5B, a stop layer 42 may be formed in the slit SL. The stop layer 42 may include at least one of a conductive pattern 42A and a liner 42B. For example, the liner 42B and the conductive pattern 42A may be formed by forming a liner layer and a conductive layer in the slit SL and then etching the liner layer and the conductive layer. Through this, a support SP including the insulating plug 41 and the stop layer 42 may be formed. An upper surface of the support SP may include a curved surface CV or may be flat.

According to the manufacturing method described above, the void V in the support SP may be opened, and the stop layer 42 may be formed in the opened void V. Accordingly, the void V in the support SP may be removed, and stress or a defect caused by the void V may be reduced. In addition, the support SP may be formed at the boundary BD between the interlayer insulating layer ILD and the stack ST. Accordingly, even though a defect occurring in a manufacturing process is transferred along the boundary BD, the defect may be stopped through the support SP.

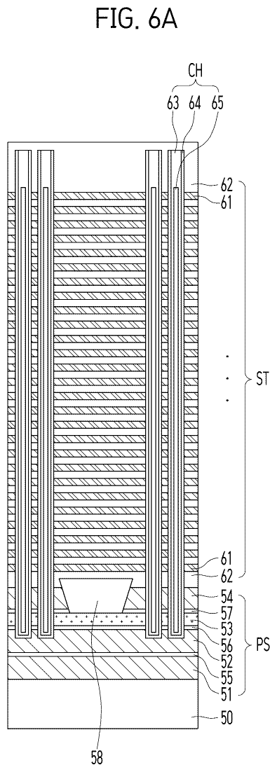

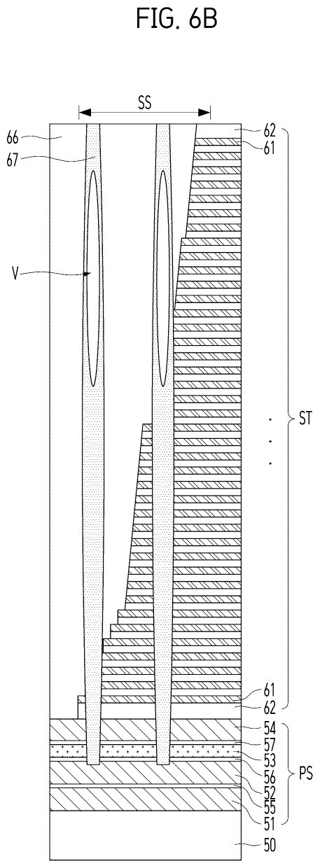

FIGS. 6A, 7A, 8A, 9A, 10A, 11A, 12A, and 13A and FIGS. 6B, 7B, 8B, 9B, 10B, 11B, 12B, and 13B are diagrams for describing a manufacturing method of a semiconductor device in accordance with an embodiment of the present disclosure. FIGS. 6A, 7A, 8A, 9A, 10A, 11A, 12A, and 13A are cross-sectional views of a cell region, and FIGS. 6B, 7B, 8B, 9B, 10B, 11B, 12B, and 13B are cross-sectional views of an edge of a semiconductor chip CHIP, an edge of a contact region CTR, or an edge of a plane PL.

Referring to FIGS. 6A and 6B, a preliminary source structure PS including a source sacrificial layer 53 may be formed on a lower structure 50. The lower structure 50 may include a substrate, a peripheral circuit, an interlayer insulating layer, and the like. The preliminary source structure PS may include a first source layer 52, a second source layer 54, and the source sacrificial layer 53 located between the first source layer 52 and the second source layer 54. The preliminary source structure PS may further include a first protective layer 56 located between the first source layer 52 and the source sacrificial layer 53 and a second protective layer 57 located between the source sacrificial layer 53 and the second source layer 54. The preliminary source structure PS may further include a sub-source layer 51 and an insulating layer 55 located between the sub-source layer 51 and the first source layer 52. For example, the first source layer 52, the second source layer 54, and the sub-source layer 51 may each include polysilicon, and the first protective layer 56, the second protective layer 57, and the insulating layer 55 may each include oxide. The sub-source layer 51 may be disposed on the lower structure 50.

Subsequently, a stack ST may be formed on the preliminary source structure PS. The stack ST may include first material layers 61 and second material layers 62 that are alternately stacked. The first material layers 61 may each include a material having a high etching selectivity with respect to the second material layers 62. For example, the first material layers 61 may each include a sacrificial material such as nitride or a conductive material such as polysilicon or metal. The second insulating layers 62 may each include an insulating material such as oxide.

For example, in an embodiment, before the stack ST is formed, an etch stop pattern 58 may be formed on the preliminary source structure PS. The etch stop pattern 58 may be a pattern that is to be used as an etch stop layer in a subsequent process of forming a second slit. The etch stop pattern 58 may include a material having a high etching selectivity with respect to the first and second material layers 61 and 62, and may include tungsten.

Subsequently, a channel structure CH may be formed. The channel structure CH may extend into the preliminary source structure PS through the stack ST. For example, the channel structure CH may pass through the second source layer 54, the second protective layer 57, the source sacrificial layer 53, and the first protective layer 56, and may extend into the first source layer 52. The channel structure CH may include a channel layer 63, a memory layer 64 surrounding the channel layer 63, and an insulating core 65 located in the channel layer 63. The memory layer 64 may include a blocking layer, a data storage layer, and a tunneling layer. Subsequently, a second material layer 62 may be additionally formed on the stack ST to cover an upper surface of the channel structure CH.

Subsequently, a staircase structure SS may be formed by patterning the stack ST as shown in FIG. 6B. The staircase structures SS may be formed to have different shapes depending on the regions of the semiconductor chip CHIP. For example, at the edge of the semiconductor chip CHIP, the edge of the contact region CTR, or the edge of the plane PL, the stack ST may include the staircase structure SS over the entire sidewall.

Subsequently, an interlayer insulating layer 66 may be formed. The interlayer insulating layer 66 may be disposed at a level corresponding to the stack ST. The interlayer insulating layer 66 may contact the sidewall of the stack ST, and may contact the staircase structure SS.

Subsequently, an insulating plug 67 may be formed. A plurality of insulating plugs 67 may be formed spaced apart from each other. For example, a contact hole extending into the preliminary source structure PS through the interlayer insulating layer 66 and/or the stack ST may be formed, and the insulating plug 67 may be formed in the contact hole. The insulating plug 67 may pass through the second source layer 54, the second protective layer 57, the source sacrificial layer 53, and the first protective layer 56, and may extend into the first source layer 52. The insulating plug 67 may have a cross section with a bowing shape, and may include a void V therein.

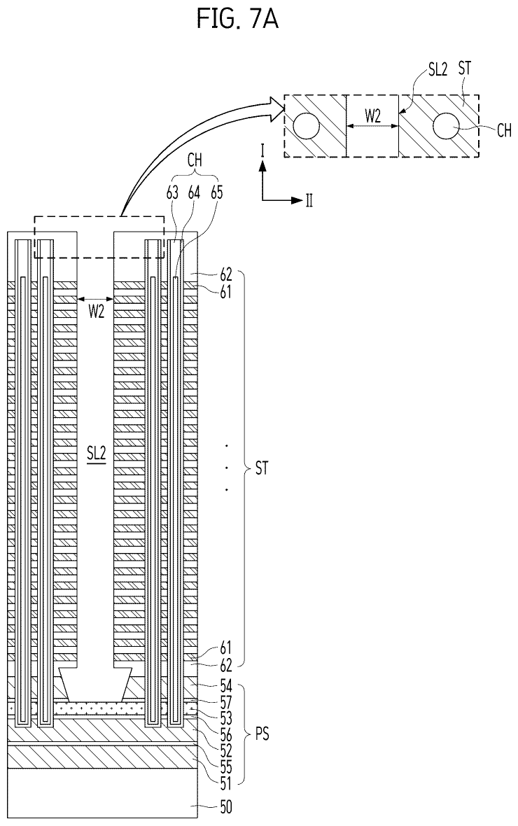

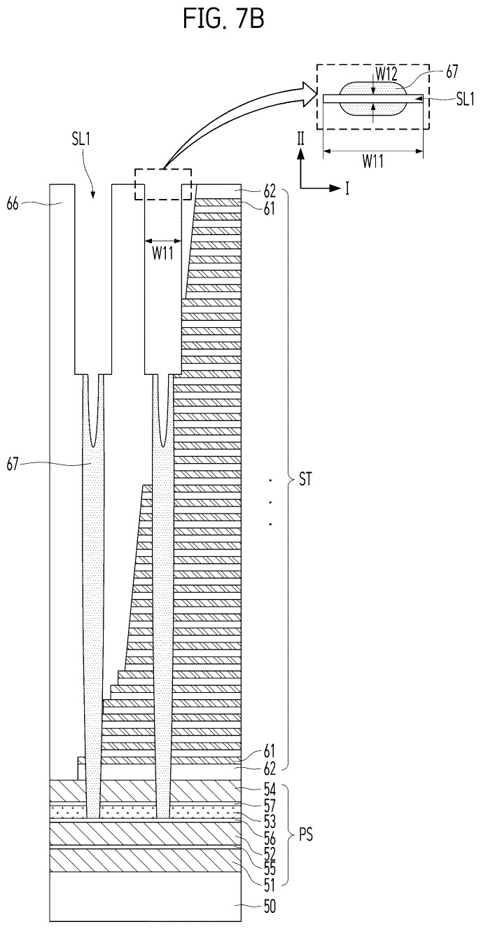

Referring to FIGS. 7A and 7B, a first slit SL1 extending through the interlayer insulating layer 66 and/or the stack ST may be formed. For example, the first slit SL1 may be formed by etching the insulating plug 67, the interlayer insulating layer 66, and/or the stack ST. The first slit SL1 may have a first width W11 in the first direction I and a first width W12 in the second direction II. The void V may be opened by the first slit SL1, and the first slit SL1 and the void V may be connected to each other. The first width W11 may be wider than a width of the insulating plug 67, and through this, the void V may be sufficiently opened.

A second slit SL2 extending through the stack ST and exposing the etch stop pattern 58 may be formed. The second slit SL2 may be disposed between the channel structures CH, and may have a second width W2. Subsequently, the etch stop pattern 58 may be removed through the second slit SL2.

The second slit SL2 and the first slit SL1 may be simultaneously formed. The second slit SL2 may have the second width W2, and the first slit SL1 may have the first width W12 that is thinner than the second width W2. Because the first slit SL1 has a thinner width than the second slit SL2, even though the first slit SL1 and the second slit SL2 are simultaneously etched, the first slit SL1 may be formed at a shallower depth than the second slit SL2. Because both the first slit SL1 and the second slit SL2 extend in the first direction I, the consistency of patterns may be maintained during an etching process.

For example, in an embodiment, the second slit SL2 may be disposed in the cell region, and may extend to the contact region. However, the second slit SL2 might not be disposed at the edge of the semiconductor chip CHIP, the edge of the contact region CTR, and the edge of the plane PL.

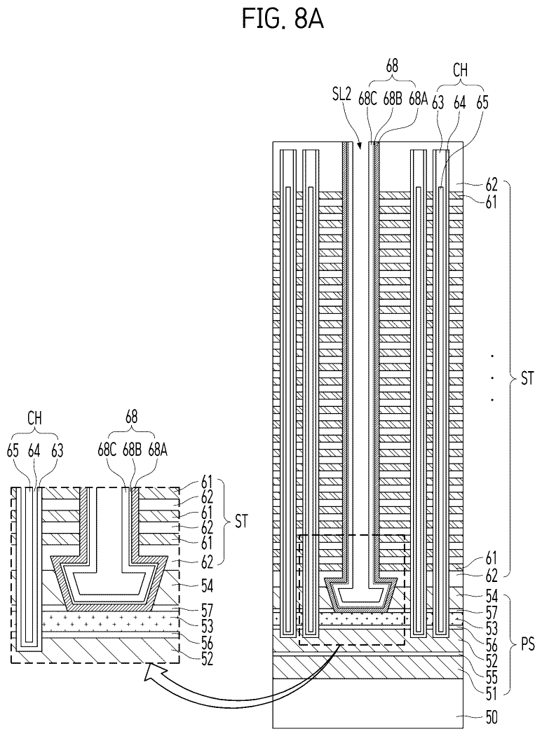

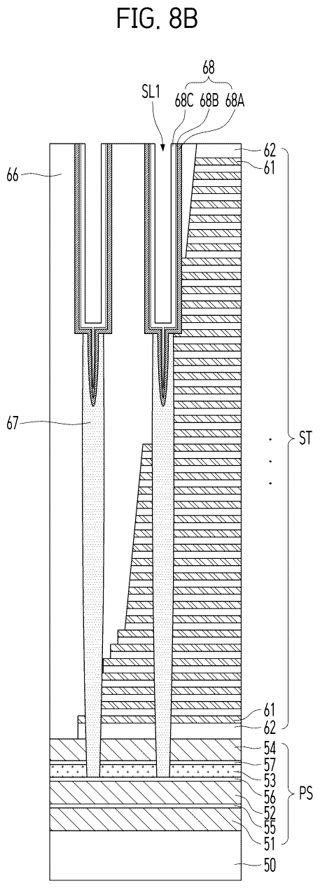

Referring to FIGS. 8A and 8B, a liner 68 may be formed in the first slit SL1 and the second slit SL2. The liner 68 may be formed along an inner surface of the first slit SL1, and a central region of the first slit SL1 may be opened. The liner 68 may be formed along an inner surface of the void V, and may completely fill or partially fill the void V.

The liner 68 may be used to protect the stack ST in a subsequent process of etching the memory layer 64. The liner 68 may be composed of a single layer or a multilayer layer. For example, a first nitride layer 68A may be formed, an oxide layer 68B may be formed on the first nitride layer 68A, and a second nitride layer 68C may be formed on the oxide layer 68B. For example, the void V may be completely filled with the first nitride layer 68A.

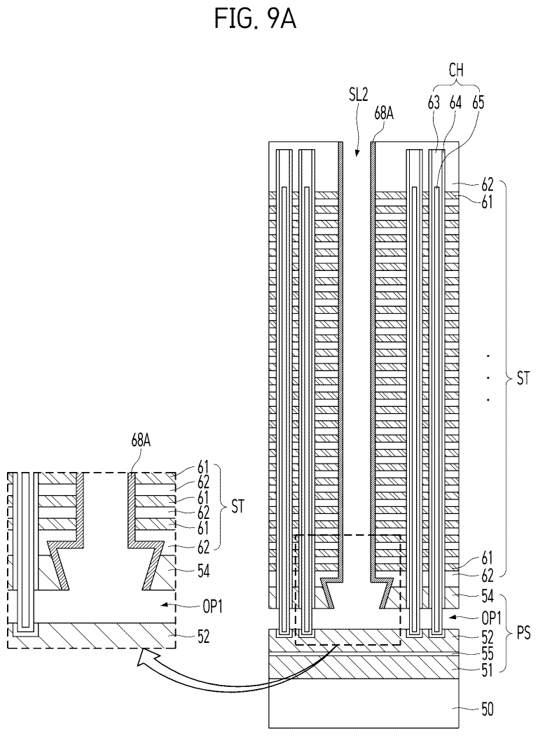

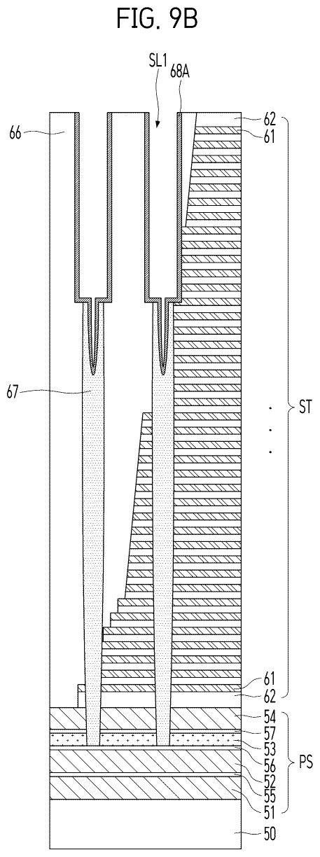

Referring to FIGS. 9A and 9B, a first opening OP1 may be formed by removing the source sacrificial layer 53 through the second slit SL2. Subsequently, the memory layer 64 may be etched so that the channel layer 63 is exposed. For example, the blocking layer, the data storage layer, and the tunneling layer may be etched using a dry cleaning process. In this process, the first protective layer 56 and the second protective layer 57 may be etched, and the first source layer 52 and the second source layer 54 may be exposed in the first opening OP1. In addition, the second nitride layer 68C and the oxide layer 68B in the second slit SL2 and the first slit SL1 may be etched to expose the first nitride layer 68A in the second slit SL2 and the first slit SL1. The second nitride layer 68C and the oxide layer 68B in the second slit SL2 and the first slit SL1 may be removed, while the first nitride layer 68A in the second slit SL2 and the first slit SL1 remain.

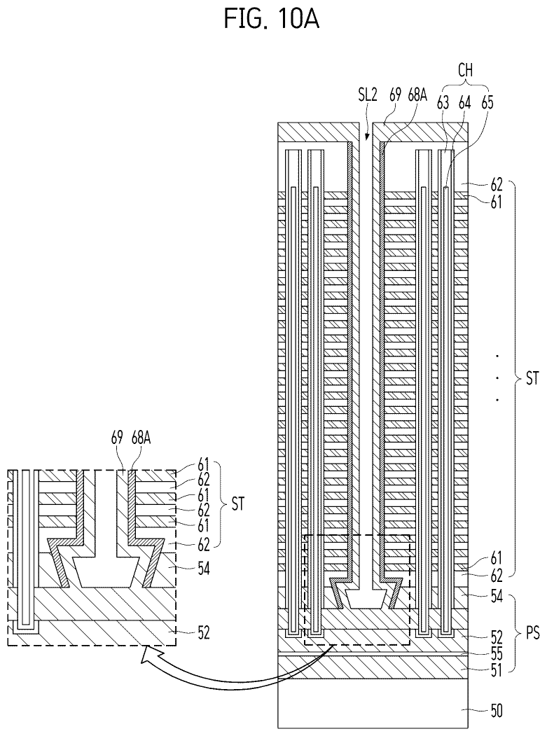

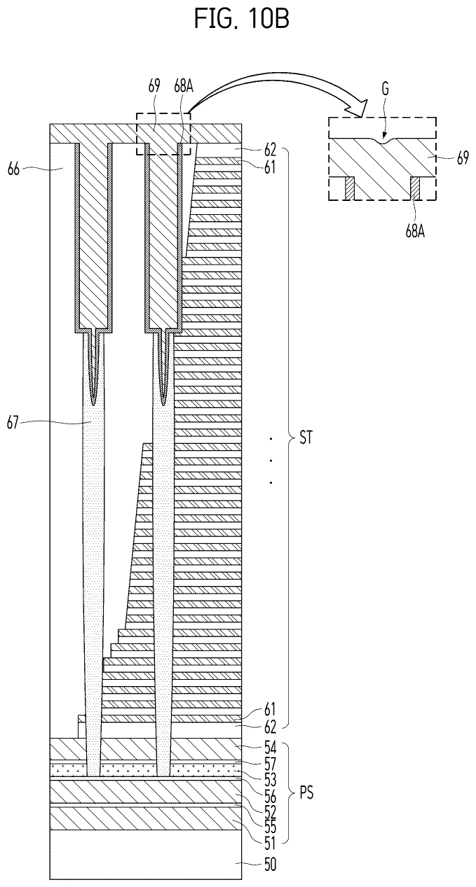

Referring to FIGS. 10A and 10B, a conductive layer 69 may be formed to fill the first opening OP1. The conductive layer may extend along the sidewall of second slit SL2. The conductive layer 69 may fill the first slit SL1, and may also be formed on an upper surface of the stack ST. The conductive layer 69 may leave the core of the second slit SL2 open. When the void V is not completely filled with the liner 68, the conductive layer 69 may be formed in the void V. The conductive layer 69 may include a groove G located on an upper surface thereof to correspond to the first slit SL1.

The conductive layer 69 may include a material having higher, or superior rigidity than the insulating plug 67. For example, the conductive layer 69 may include a material having a higher density or a greater elastic modulus than the insulating plug 67. The insulating plug 67 may include silicon oxide, and the conductive layer 69 may include polysilicon or tungsten.

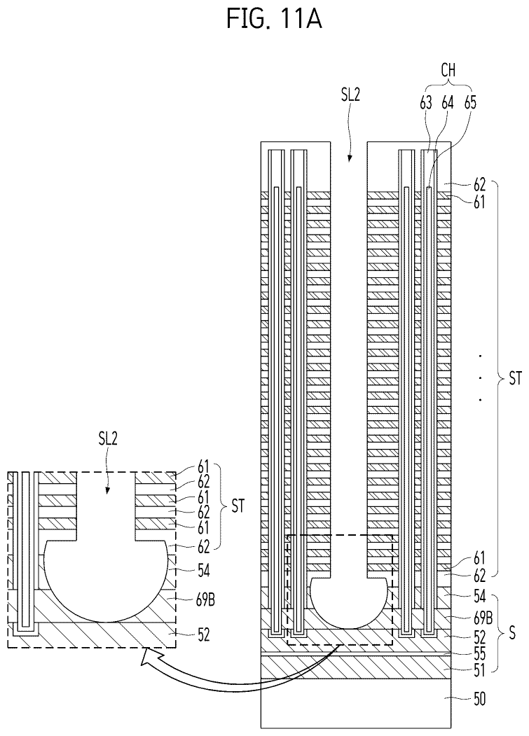

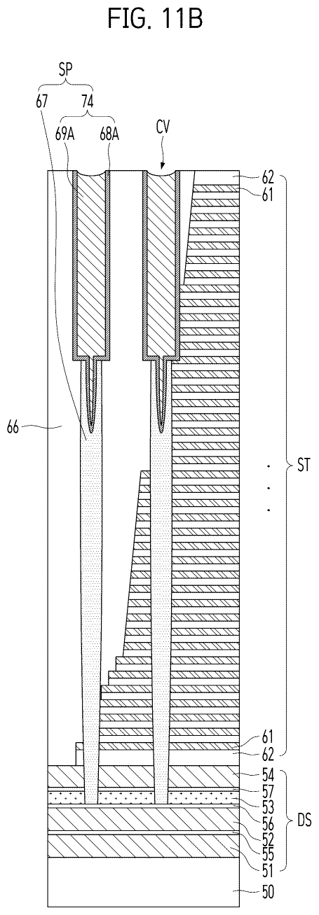

Referring to FIGS. 11A and 11B, a conductive pattern 69A may be formed in the first slit SL1 by etching the conductive layer 69. In the process of etching the conductive layer 69, the groove G on the upper surface of the conductive layer 69 may be transferred, and an upper surface of the conductive pattern 69A may include a curved surface CV. Through this, a stop layer 74 including the conductive pattern 69A and the first nitride layer 68A may be formed. In addition, a support SP including the insulating plug 67 and the stop layer 74 may be formed.

A third source layer 69B may be formed in the first opening OP1 by etching the conductive layer 69. For example, the conductive layer 69 may be etched using a wet etching process. Through this, a source structure S including the first source layer 52, the second source layer 54, the third source layer 69B, the sub-source layer 51, and the insulating layer 55 may be formed. A portion of the preliminary source structure PS where the source sacrificial layer 53 remains may be defined as a dummy source structure DS.

Subsequently, the first nitride layer 68A in the second slit SL2 may be removed. The first nitride layer 68A in the first slit SL1 is covered by the conductive pattern 69A, and thus, might not be removed.

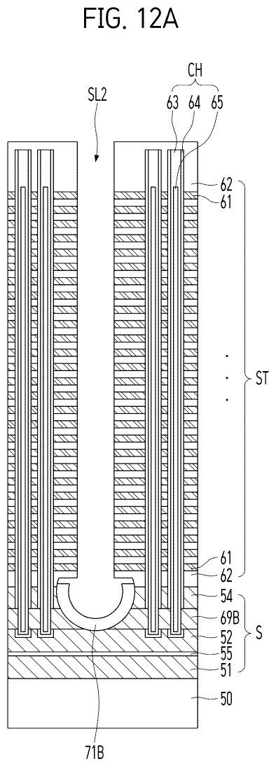

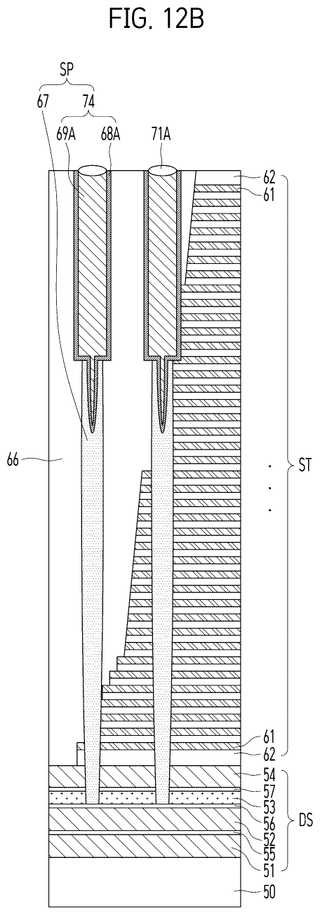

Referring to FIGS. 12A and 12B, first and second protective patterns 71A and 71B may be formed using an oxidation process. Forming the first protective pattern 71A may include selectively oxidizing a surface of the stop layer 74 or a surface of the conductive pattern 69A. The second protective pattern 71B may be formed by selectively oxidizing the surfaces of the first source layer 52, the second source layer 54, and the third source layer 69B which are exposed through the second slit SL2.

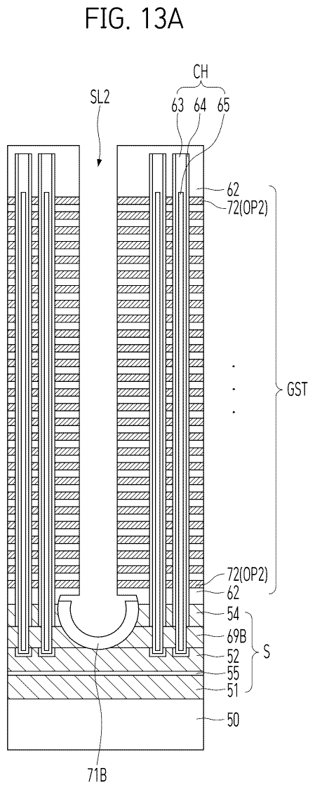

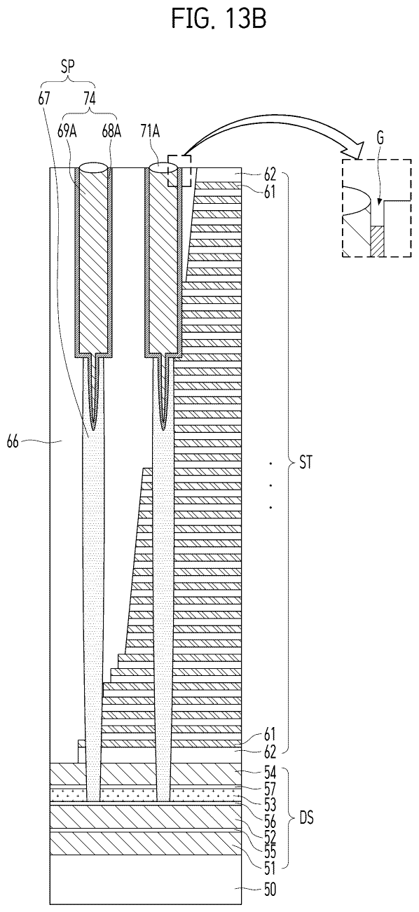

Referring to FIGS. 13A and 13B, the first material layers 61 may be replaced with third material layers 72. For example, second openings OP2 may be formed by selectively etching the first material layers 61 through the second slit SL2. When the first material layers 61 are etched, the source structure S may be protected by the second protective pattern 71B. Subsequently, the third material layers 72 may be formed in the second openings OP2, respectively. The third material layers 72 may each include a conductive material such as tungsten or molybdenum. The third material layers 72 may be used as gate lines such as select lines and word lines. Through this, a gate structure GST including the second material layers 62 and the third material layers 72 that are alternately stacked may be formed. A portion where the first material layers 61 are not replaced with the third material layers 72 may remain as the stack ST.

When the first material layers 61 are selectively etched, the stop layer 74 or the conductive pattern 69A may be protected by the first protective pattern 71A. When the first material layers 61 are selectively etched, the first nitride layer 68A may be partially etched, and a groove G may be formed around the conductive pattern 69A. The groove G may be filled with an interlayer insulating layer in a subsequent process. For example, the groove G may be only partially filled, and a portion of the groove G that is not filled may be defined as a void.

For example, in an embodiment, when the first material layers 61 each include a conductive material, a process of replacing the first material layers 61 with the third material layers 72 may be omitted. In such a case, the stack ST of the cell region and the contact region may be used as a gate electrode.

Subsequently, although not illustrated in FIGS. 13A and 13B, a slit structure may be formed in the second slit SL2. For example, an insulating spacer may be formed on an inner wall of the second slit SL2, and the source structure S may be exposed by etching the second protective pattern 71B. Subsequently, a source contact plug electrically connected to the source structure S may be formed in the second slit SL2.

According to the manufacturing method described above, the source structure S may be formed in the cell region, and the support SP may be formed at the edge of the semiconductor chip CHIP, the edge of the contact region CTR, or the edge of the plane PL. The first slit SL1 may be formed using a process of forming the second slit SL2, and the void V may be opened. The stop layer 74 may be formed in the first slit SL1 using a process of forming the third source layer 69B. Through this, the support SP including the conductive pattern 69A and/or the first nitride layer 68A may be formed.

In a process of manufacturing the semiconductor device, stress may be induced by the void V, shrinkage of a layer, and the like, and a defect may occur due to the stress. A crack may occur, and a metal wiring line exposed by the crack may be oxidized. Such a defect may be transferred along a boundary between the interlayer insulating layer 66 and the stack ST. However, according to an embodiment of the present disclosure, it is possible to block the transfer of the defect using the support SP.

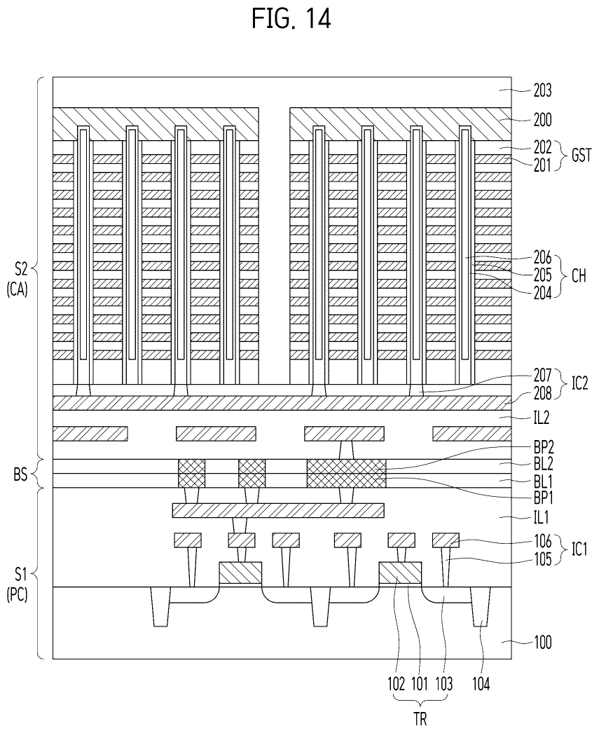

FIG. 14 is a diagram illustrating the structure of a semiconductor device in accordance with an embodiment of the present disclosure. Hereinafter, any content overlapping with the previously described content may be omitted.

Referring to FIG. 14, the semiconductor device may include a first semiconductor structure S1, a second semiconductor structure S2, and a bonding structure BS located between the first semiconductor structure S1 and the second semiconductor structure S2. The first semiconductor structure S1 and the second semiconductor structure S2 may be formed by separate processes, and may be electrically connected to each other by the bonding structure BS. For example, the first semiconductor structure S1 may include a peripheral circuit PC, and the second semiconductor structure S2 may include a memory cell array CA.

The first semiconductor structure S1 may include a substrate 100, a transistor TR, a first interconnection structure IC1, and a first interlayer insulating layer IL1. An active region may be defined by an element isolation layer 104 in the substrate 100, and the transistor TR may be disposed in the active region. The transistor TR may include a gate insulating layer 101, a gate electrode 102, and a junction 103. The transistor TR may belong to the peripheral circuit PC.

The first interconnection structure IC1 may be disposed in the first interlayer insulating layer IL1, and may include a via 105, a wiring line 106, and the like. The first interconnection structure IC1 may be electrically connected to the peripheral circuit PC, and may be electrically connected to the transistor TR.

The second semiconductor structure S2 may include a source structure 200, a gate structure GST, an insulating layer 203, a second interconnection structure IC2, and a second interlayer insulating layer IL2. The source structure 200 may be disposed above or below the gate structure GST. The source structure 200 may include a conductive material such as polysilicon or metal. The second semiconductor structure S2 may further include the stack ST and the support SP described above with reference to FIGS. 1A to 1C and FIGS. 2A to 2D.

The gate structure GST may include conductive layers 201 and insulating layers 202 that are alternately stacked. The conductive layers 201 may be gate lines such as a source select line, a drain select line, and word lines. A channel structure CH may extend through the gate structure GST, and may be connected to the source structure 200. The channel structure CH may include a channel layer 204, a memory layer 205, and an insulating core 206.

The second interconnection structure IC2 may be disposed in the second interlayer insulating layer IL2 and may include a via 207, a wiring line 208, and the like. The second interconnection structure IC2 may be electrically connected to the channel structure CH, the gate structure GST, and the like.

The bonding structure BS may include a first bonding layer BL1, a second bonding layer BL2, a first bonding pad BP1, and a second bonding pad BP2. The first bonding layer BL1 and the second bonding layer BL2 may contact each other, and the first bonding pad BP1 and the second bonding pad BP2 may contact each other. The first bonding layer BL1 and the second bonding layer BL2 may each include SiCN, tetra ethyl ortho silicate (TEOS), or the like. The first bonding pad BP1 may be electrically connected to the first interconnection structure IC1, and the second bonding pad BP2 may be electrically connected to the second interconnection structure IC2. The memory cell array CA and the peripheral circuit PC may be electrically connected to each other through the first bonding pad BP1 and the second bonding pad BP2.

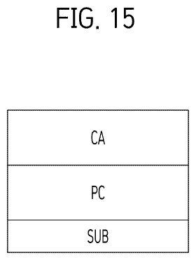

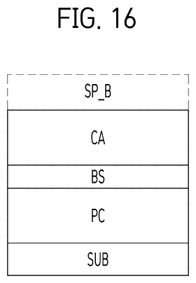

The structure and the manufacturing method according to the above-described embodiments may be applied to semiconductor devices of various structures. FIGS. 15 and 16 are schematic illustrations of a configuration of a semiconductor device to which the above-described embodiments are applicable.

FIG. 15 is a configuration diagram of a semiconductor device according to an embodiment of the present disclosure.

Referring to FIG. 15, the semiconductor device may include a substrate SUB, a peripheral circuit PC, and a memory cell array CA. For example, the peripheral circuit PC and the memory cell array CA may be formed on the same substrate.

The substrate SUB may be made of or include a semiconductor material. In an embodiment, the semiconductor material may include at least one of a group IV semiconductor, a group III-V compound semiconductor, and a group II-VI compound semiconductor. Here, the group IV semiconductor may include single crystal silicon Si, polycrystalline silicon, germanium Ge, or silicon germanium SiGe. The group III-V compound semiconductor may include Gallium Arsenide (GaAs), Gallium Nitride (GaN), Gallium Phosphide (GaP), Gallium Arsenide Phosphide (GaAsP), Gallium Indium Arsenide Phosphide (GaInAsP), Aluminum Arsenide (AlAs), Aluminum Gallium (AlGa), Indium Phosphide (InP), Indium Antimonide (InSb), or Indium Gallium Arsenide (InGaAs). The group II-VI compound semiconductor may include Zinc Sulfide (ZnS), Zinc Oxide (ZnO), or Cadmium Sulfide (CdS).

The substrate SUB may include a dielectric layer. The substrate SUB may be a silicon-on-insulator (SOI) substrate, a germanium-on-insulator (GeOI) substrate, or a glass substrate. The substrate SUB may include an organic material. In an embodiment, the substrate SUB may include graphene, e.g., epitaxial graphene.

The substrate SUB may be a bulk wafer or an epitaxial layer grown in a selective epitaxial growth (SEG) method. The substrate SUB may be a layer formed in a metal induced lateral crystallization (MILC) method and may partially include metal. The substrate SUB may have a single crystalline, polycrystalline, or amorphous state. The substrate SUB may include an impurity of group II, group III, group IV, group V, or group VI. In an embodiment, the substrate SUB may include an n-well region doped with an n-type impurity and/or a p-well region doped with a p-type impurity.

The peripheral circuit PC may be disposed between the substrate SUB and the memory cell array CA. The peripheral circuit PC may include a row decoder, a column decoder, a page buffer, a logic circuit, a control circuit, a sense amplifier, an input/output circuit, and the like. In an embodiment, the peripheral circuit PC may include an NMOS transistor, a PMOS transistor, a resistor, a capacitor, and the like. The peripheral circuit PC may further include an interconnection structure. The interconnection structure may be used as a path for transferring an operation voltage, and may include a contact plug, a line, and the like.

The memory cell array CA may include memory cells. In an embodiment, the memory cell array CA may include memory strings connected between a source line and a bit line, and each memory string may include stacked memory cells. In an embodiment, the memory cell array CA may include memory cells connected between a word line and a bit line. The memory cell array CA may further include an interconnection structure.

FIG. 16 is a configuration diagram of a semiconductor device according to an embodiment of the present disclosure.

Referring to FIG. 16, the semiconductor device may include a substrate SUB, a peripheral circuit PC, a bonding structure BS, and a memory cell array CA. Here, the peripheral circuit PC and the memory cell array CA may be respectively formed on separate substrates and then bonded. The semiconductor device may further include a support base SP_B.

The substrate SUB may be used as a support in a process of forming the peripheral circuit PC. The support base SP_B may be used as a support in a process of forming the memory cell array CA. In an embodiment, after respectively manufacturing a first wafer including the memory cell array CA and a second wafer including the peripheral circuit PC, the first wafer and the second wafer may be electrically connected by the bonding structure BS. After bonding, at least a portion of the support base SP_B of the first wafer may be removed. The support base SP_B may be completely removed or may partially remain on the memory cell array CA.

The support base SP_B may be a semiconductor substrate, an insulating substrate, a silicon-on-insulator (SOI) substrate, a germanium-on-insulator (GeOI) substrate, or the like. The support base SP_B may be a bulk wafer, an epitaxial layer grown in a selective epitaxial growth (SEG) method, or a layer formed in a metal induced lateral crystallization (MILC) method. The support base SP_B may have a single crystalline, polycrystalline, or amorphous state. The support base SP_B may include an impurity of group II, group III, group IV, group V, or group VI.

The bonding structure BS may be for connecting the memory cell array CA and the peripheral circuit PC. In an embodiment, the memory cell array CA and the peripheral circuit PC may be bonded in a wafer-on-wafer bonding method, a chip-on-wafer bonding method, a chip-on-chip bonding method, or the like. The bonding structure BS may include a bonding pad, a bonding layer, a bonding interface, and the like. The bonding pad may include a metal such as copper and aluminum, and/or an alloy. The bonding interface may include a non-metal-non-metal interface, a metal-metal interface, or the like. The memory cell array CA and the peripheral circuit PC may be electrically connected by the bonding structure BS.

For example, in an embodiment, an interconnection structure included in the memory cell array CA and/or the peripheral circuit PC may be directly connected without a bonding pad. In an embodiment, a bonding layer included in the memory cell array CA and a bonding layer included in the peripheral circuit PC may be bonded to form a bonding interface, and the interconnection structure included in the memory cell array CA and the interconnection structure included in the peripheral circuit PC may be directly connected. Through this, contact plugs, lines, and the like formed on different wafers may be electrically connected without a separate bonding pad.

Other configurations may be equal or similar to those described above with reference to FIG. 15.

For example, the semiconductor device may have a structure in which the embodiments described above with reference to FIGS. 15 and 16 are combined or may have a partially modified structure. In the embodiment described with reference to FIGS. 15 and 16, positions of the memory cell array CA and the peripheral circuit PC may be changed. At least one memory cell array CA and/or at least one peripheral circuit PC may be additionally bonded to the embodiment described with reference to FIGS. 15 and 16. In an embodiment, a portion of the peripheral circuitry PC may be disposed in the memory cell array CA.

Although embodiments according to the technical ideas of the present disclosure have been described above with reference to the accompanying drawings, this is only for describing the embodiments, and the present disclosure is not limited to the above embodiments. Various types of substitutions, modifications, changes, and combinations for the embodiments may be made by those skilled in the art, without departing from the technical ideas of the present disclosure defined in the following claims, and it should be construed that these substitutions, modifications, changes, and combinations belong to the scope of the present disclosure. Furthermore, the embodiments may be combined to form additional embodiments.

What is claimed is:

1. A semiconductor device comprising:
a stack including a staircase structure;
an interlayer insulating layer disposed at a level corresponding to the stack, the interlayer insulating layer being in contact with the staircase structure in a first direction, wherein a boundary between the interlayer insulating layer and the staircase structure is extending in a second direction intersecting the first direction; and
at least one support disposed at the boundary and including an insulating plug extending through the interlayer insulating layer and the stack and a stop layer extending in the first direction through the insulating plug.

2. The semiconductor device of claim 1, wherein a width of the insulating plug in the first direction is wider than a width of the insulating plug in the second direction.

3. The semiconductor device of claim 1, wherein a width of the stop layer in the first direction is wider than a width of the stop layer in the second direction.

4. The semiconductor device of claim 1, wherein the at least one support includes a plurality of supports arranged in the second direction along the boundary.

5. The semiconductor device of claim 1, wherein the stop layer comprises:
a first portion having a slit shape traversing the insulating plug; and
a second portion protruding from a lower surface of the first portion.

6. The semiconductor device of claim 1, wherein the stop layer has a shorter height than the insulating plug.

7. The semiconductor device of claim 1, wherein the stop layer has a higher density than the insulating plug.

8. The semiconductor device of claim 1, wherein the stop layer has a greater elastic modulus than the insulating plug.

9. The semiconductor device of claim 1, wherein the insulating plug includes oxide, and the stop layer includes at least one of nitride and polysilicon.

10. The semiconductor device of claim 1, wherein the stop layer comprises:
a conductive pattern; and
a liner surrounding the conductive pattern.

11. The semiconductor device of claim 10, wherein the insulating plug includes oxide, the conductive pattern includes polysilicon, and the liner includes nitride.

12. The semiconductor device of claim 1, further comprising:
a peripheral circuit located below the stack; and
a contact plug extending through the stack and electrically connected to the peripheral circuit.

13. The semiconductor device of claim 1, further comprising:
channel structures extending through the stack; and
a slit structure located between the channel structures and extending in the first direction through the stack.

14. The semiconductor device of claim 1, wherein the stack is disposed at an edge of a semiconductor chip.

15. The semiconductor device of claim 1, wherein the stack is located between adjacent planes.

16. The semiconductor device of claim 1, wherein the stack is located between adjacent memory blocks.

17. A semiconductor device comprising:
a stack including first material layers and second material layers that are alternately stacked;
an interlayer insulating layer disposed at a level corresponding to the stack, the interlayer insulating layer being in contact with the stack in a first direction, wherein a boundary between the interlayer insulating layer and the stack is extending in a second direction intersecting the first direction;
an insulating plug disposed at the boundary;
a conductive pattern having a slit shape traversing the insulating plug and having a wider width than the insulating plug in the first direction; and
a liner surrounding the conductive pattern.

18. The semiconductor device of claim 17, wherein the conductive pattern and the liner each have a higher density than the insulating plug.

19. The semiconductor device of claim 17, wherein the conductive pattern and the liner each have a greater elastic modulus than the insulating plug.
